(19) United States
(12) Patent Application Publication
(10) Pub. No.: US 2017/0162426 A1
(43) Pub. Date: Jun. 8, 2017

(54) SPIN CHUCK WITH GAS LEAKAGE PREVENTION

(71) Applicant: LAM RESEARCH AG, Villach (AT)

(72) Inventors: Andreas GLEISSNER, Dobriach (AT); Bernhard LOIDL, Villach (AT); Bhaskar BANDARAPU, Villach (AT); Markus JUNK, Villach (AT)

(73) Assignee: LAM RESEARCH AG

(21) Appl. No.: 14/960,169

(22) Filed: Dec. 4, 2015

(51) Int. Cl. H01L 21/687; H01L 21/67; C23C 16/455; C23C 14/50; C23C 16/458

(52) U.S. Cl. CPC H01L 21/68785; C23C 14/505; C23C 16/4585; C23C 16/45565; C23C 16/45561; C23C 16/4584; H01L 21/67069; H01L 21/67034; H01L 21/68735; H01L 21/68764

(57) ABSTRACT

An apparatus for processing wafer-shaped articles, comprises a process chamber, and a spin chuck positioned inside the process chamber. The spin chuck is configured to hold a wafer-shaped article at a predetermined process position. A plate covers the spin chuck and is affixed to or formed integrally with the spin chuck for rotation therewith, the plate having a central opening. A nozzle assembly extends into the process chamber such that a discharge end of the nozzle assembly passes through the central opening of the plate to define a gap between the plate and the nozzle assembly, the gap extending from an upper inlet end to a lower outlet end. The nozzle assembly comprises at least one side nozzle positioned to direct a gas flow adjacent to the gap and upstream of the lower outlet end, and configured to generate a reduced pressure at a position upstream of the lower outlet end of the gap, thereby to control gas flow through the gap from the upper inlet end toward the lower outlet end.

### BACKGROUND OF THE INVENTION

1. Field of the Invention

The invention relates generally to an apparatus for processing wafer-shaped articles, such as semiconductor wafers, and more particularly relates to such an apparatus comprising a spin chuck designed to prevent unintended gas flow within the chuck.

2. Description of Related Art

Semiconductor wafers are subjected to various surface treatment processes such as etching, cleaning, polishing and material deposition. To accommodate such processes, a single wafer may be supported in relation to one or more treatment fluid nozzles by a chuck associated with a rotatable carrier, as is described for example in U.S. Pat. Nos. 4,903,717 and 5,513,668.

Alternatively, a chuck in the form of a ring rotor adapted to support a wafer may be located within a closed process chamber and driven without physical contact through an active magnetic bearing, as is described for example in International Publication No. WO 2007/101764 and U.S. Pat. No. 6,485,531.

When a stationary nozzle assembly passes through a rotary part of the chuck, a mechanical clearance is necessary. Such clearances, however, can result in unintended gas flows that can adversely affect processing of wafers.

### SUMMARY OF THE INVENTION

The present inventors have developed an improved apparatus for treatment of wafer-shaped articles, in which a spin chuck is designed to prevent unintended gas flow within the chuck.

Thus, in one aspect, the present invention relates to an apparatus for processing wafer-shaped articles, comprising a process chamber, and a spin chuck positioned inside the process chamber. The spin chuck is configured to hold a wafer-shaped article at a predetermined process position. A plate covers the spin chuck and is affixed to or formed integrally with the spin chuck for rotation therewith, the plate having a central opening. A nozzle assembly extends into the process chamber such that a discharge end of the nozzle assembly passes through the central opening of the plate to define a gap between the plate and the nozzle assembly, the gap extending from an upper inlet end to a lower outlet end. The nozzle assembly comprises at least one side nozzle positioned to direct a gas flow adjacent to the gap and upstream of the lower outlet end, and configured to generate a reduced pressure at a position upstream of the lower outlet end of the gap, thereby to control gas flow through the gap from the upper inlet end toward the lower outlet end.

In preferred embodiments of the apparatus according to the present invention, the plate and an upper part of the process chamber define a gas distribution chamber, and wherein the plate comprises plural openings formed in each of a central and a peripheral region thereof, thereby to supply process gas from the gas distribution chamber to a surface of a wafer-shaped article when held by the spin chuck.

In preferred embodiments of the apparatus according to the present invention, at least one gas supply nozzle is positioned radially outside of the nozzle assembly, the at least one gas supply nozzle supplying process gas to the gas distribution chamber.

In preferred embodiments of the apparatus according to the present invention, the plate is domed such that a central region thereof is positioned farther from a wafer-shaped article when positioned on the spin chuck than a peripheral region thereof.

In preferred embodiments of the apparatus according to the present invention, each of the plural openings has a cross-sectional area in a range from 0.3 to 2.0 mm², preferably from 0.5 to 1.5 mm², and more preferably from 0.7 to 1.2 mm².

In preferred embodiments of the apparatus according to the present invention, the plural openings include at least 20 of the openings, more preferably at least 50 of the openings, and still more preferably at least 80 of the openings.

In preferred embodiments of the apparatus according to the present invention, the at least one side nozzle comprises at least three side nozzles, positioned symmetrically with respect to the gap.

In preferred embodiments of the apparatus according to the present invention, the at least one side nozzle comprises a constricted section having an outlet communicating with a wider section adjacent to and communicating with the upper end of the gap, thereby to generate the reduced pressure via the Venturi effect.

In preferred embodiments of the apparatus according to the present invention, the constricted section is oriented such that a flow path thereof is generally parallel to an axis of rotation of the spin chuck.

In preferred embodiments of the apparatus according to the present invention, the constricted section is oriented such that a flow path thereof extends obliquely to an axis of rotation of the spin chuck, with an inlet of the constricted section being closer to an axis of rotation of the spin chuck than the outlet.

In preferred embodiments of the apparatus according to the present invention, the nozzle assembly comprises a liquid supply conduit and a gas supply conduit, each of the liquid supply conduit and the gas supply conduit opening at the discharge end of the nozzle assembly, at a level below a lower end of the gap.

In preferred embodiments of the apparatus according to the present invention, the central opening of the plate is a circular opening having a diameter of 30-60 mm

In preferred embodiments of the apparatus according to the present invention, the spin chuck comprises a magnetic rotor, the apparatus further comprising a magnetic stator mounted outside of the process chamber and surrounding the magnetic rotor.

### BRIEF DESCRIPTION OF THE DRAWINGS

Other objects, features and advantages of the invention will become more apparent after reading the following detailed description of preferred embodiments of the invention, given with reference to the accompanying drawings, in which:

FIG. 1 is an explanatory cross-sectional side view of an apparatus according to a first embodiment of the invention;

FIG. 2 is a plan view of the outlet plate of the gas showerhead used in the embodiment of FIG. 1;

FIG. 3 is an enlarged view of the detail III in FIG. 1;

FIG. 4 is a perspective view, partly in section, showing additional details of the embodiment of FIG. 1;

FIGS. 5a, 5b and 5c are enlarged views of the detail V in FIG. 4, showing different flow conditions based on use of the apparatus according to the embodiment of FIG. 1; and

FIG. 5d is an enlarged view of the detail V in FIG. 4, showing an alternative embodiment of the side discharge nozzle.

### DETAILED DESCRIPTION OF PREFERRED EMBODIMENTS

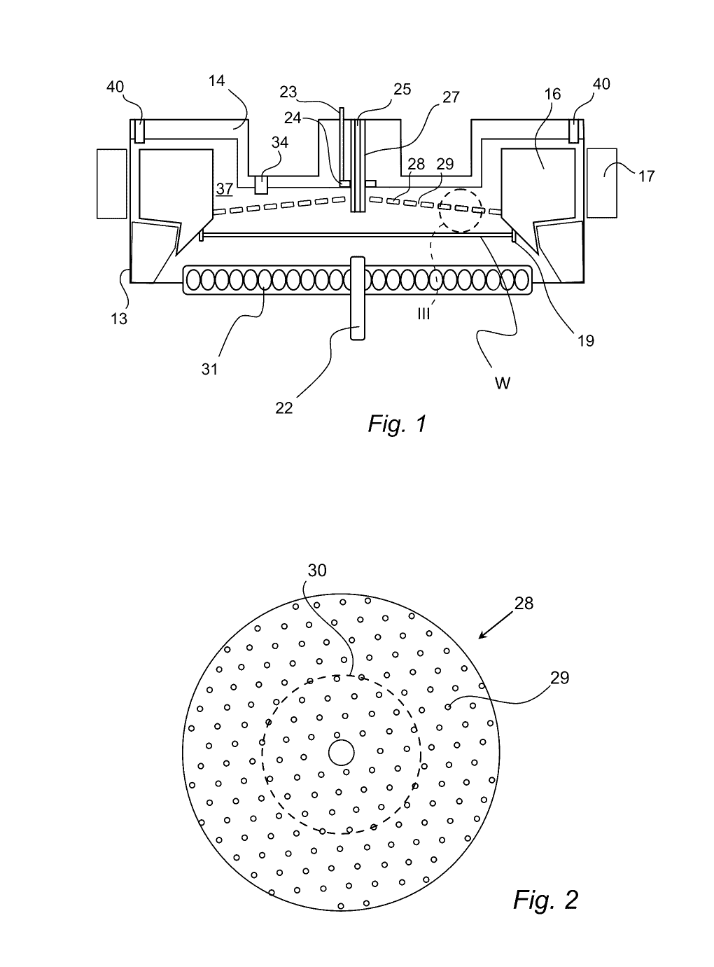

Referring now to FIG. 1, an apparatus for treating surfaces of wafer-shaped articles according to a first embodiment of the invention comprises a closed process chamber 13, in which is arranged an annular spin chuck 16. Spin chuck 16 is a magnetic rotor that is surrounded by a magnetic stator 17 positioned outside the chamber, so that the magnetic rotor is freely rotating and levitating within the chamber 13 without touching the chamber walls. The chamber 13 is closed at its upper end by lid 14 rigidly secured thereto.

Further structural details of such a magnetic rotor chuck are described, for example, in commonly-owned U.S. Pat. No. 8,646,767.

The annular spin chuck 16 has a circular series of downwardly-depending gripping pins 19, which releasably hold a wafer W during processing. A lower dispense unit 22 is provided so as to supply liquid and/or gas to the side of the wafer W that faces downwardly within chamber 13. A heater 31 is disposed within the chamber 13, so as to heat the wafer W to a desired temperature depending upon the process being performed. Heater 31 preferably comprises a multitude of blue LED lamps, whose radiation output tends to be absorbed preferentially by silicon wafers relative to the components of the chamber 13.

An upper dispense unit comprises an outer gas conduit 27 and an inner liquid conduit 25 arranged coaxially within the outer gas conduit 27. Conduits 25, 27 both traverse the lid 14, and permit liquid and gas to be supplied to the side of the wafer W that faces upwardly within chamber 13. The upper dispense unit also includes a conduit 23 that supplies gas to an annular nozzle 24 in which is formed at least one side nozzle, as will be explained in greater detail below.

A gas showerhead is delimited at its lower side by an outlet plate 28, which is also shown in plan view in FIG. 2. The outlet plate 28 comprises a multitude of discharge orifices 29, which permit process gas to pass out of the gas showerhead from the gas distribution chamber 37 to the region adjacent the upwardly facing side of the wafer W. The discharge orifices 29 in this embodiment each have a cross-sectional area in a range from 0.3 to 2.0 mm, preferably from 0.5 to 1.5 mm, and more preferably from 0.7 to 1.2 mm. There are preferably at least 20 orifices 29, more preferably at least 50, still more preferably at least 80, and even more preferably 300.

The outlet plate 28 is rigidly secured to or formed integrally with the spin chuck 16, and therefore rotates along with the spin chuck 16. On the other hand, the conduits 25, 27 are stationarily mounted in the lid 14 of chamber 13, and pass with a slight clearance through a central opening formed in the plate 28.

As shown in FIG. 2, there are a plurality of these orifices 29 in each of a central region and a peripheral region of the plate 28, wherein the central region is defined as being the area within the half-radius 30 of the plate 28, and the peripheral region is defined as being the area outside of the half-radius 30.

Returning to FIG. 1, it will be seen that the gas distribution chamber 37 is supplied with process gas through a process gas supply conduit 34, which in turn communicates with a source of process gas (not shown), which in preferred embodiments is a gas containing ozone.

Additional gas conduits 40 are provided near the outer periphery of chamber 13, and direct a purge gas such as N₂ into the gap defined between the outer periphery of spin chuck 16 and the surrounding cylindrical wall of chamber 13. Gas from nozzles 40 also forms a boundary such that process gas supplied from nozzle 34 is confined within distribution chamber 37.

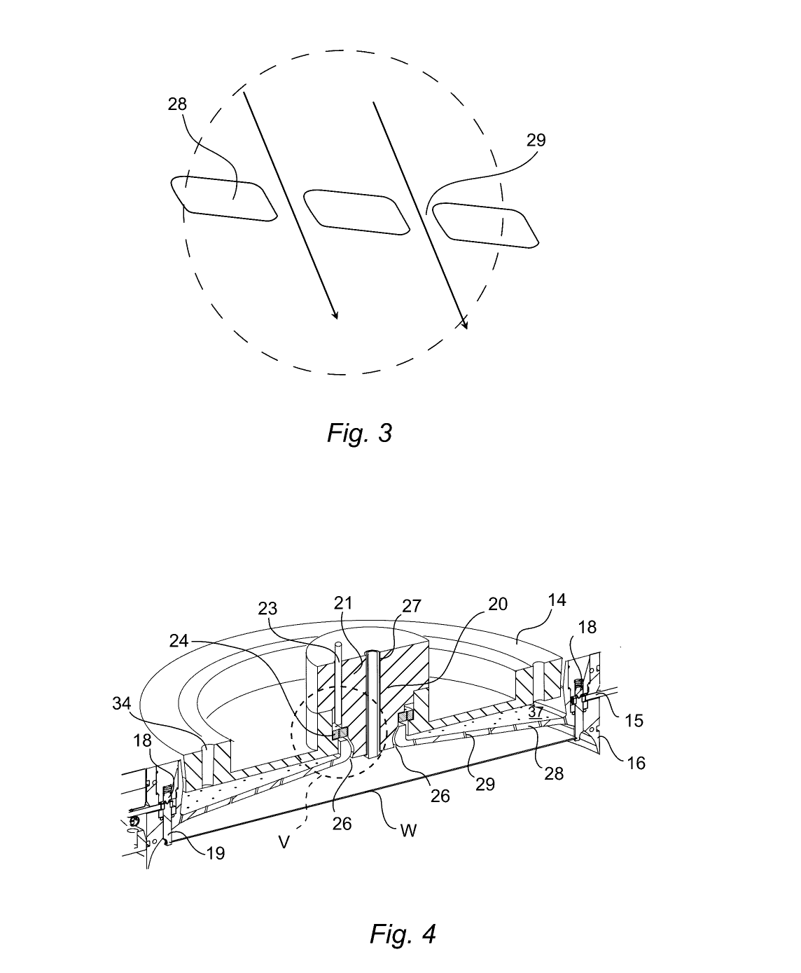

As shown in FIG. 3, the discharge orifices 29 of this embodiment are oriented at an oblique angle relative to the vertical axis of rotation of the spin chuck 16, such that the orifices are directed radially outwardly of the spin chuck 16. The inventors have found that this configuration helps to divert any liquids in the distribution chamber 37 away from the upwardly facing surface of wafer W, while permitting the process gas supplied through conduit 34 still to reach the target region adjacent the wafer W.

As shown in FIG. 4, the plate 28 in this embodiment is formed integrally with the spin chuck 16. The lower end of nozzle assembly 21 passes through a central opening in plate 28, and an annular gap 26 is defined between these two components. Nozzle assembly 21 also includes a third nozzle 24, supplied with gas from conduit 23, which directs gas adjacent this annular gap 26.

The spin chuck 16 also includes the gripping pins 19 described above, as well as needle bearings 18 that urge the pins 19 downwardly so that gear wheels at the upper ends of the pins 19 remain in continuous meshing engagement with the toothed sectors of a common ring gear 15, as described for example in commonly-owned U.S. Pat. No. 8,646,767 and U.S. published patent application no. 2015/0008632.

The clearance or annular gap 26 is necessary to permit the spin chuck 16 with integral plate 28 to rotate relative to the stationary nozzle head 21 that is mounted in the lid 14 of the apparatus. However, the present inventors have discovered that, in use of such an apparatus, a significant proportion of the flow of process gas is redirected so as to flow not through the openings 29 of the gas showerhead plate 28, but rather through the annular gap 26.

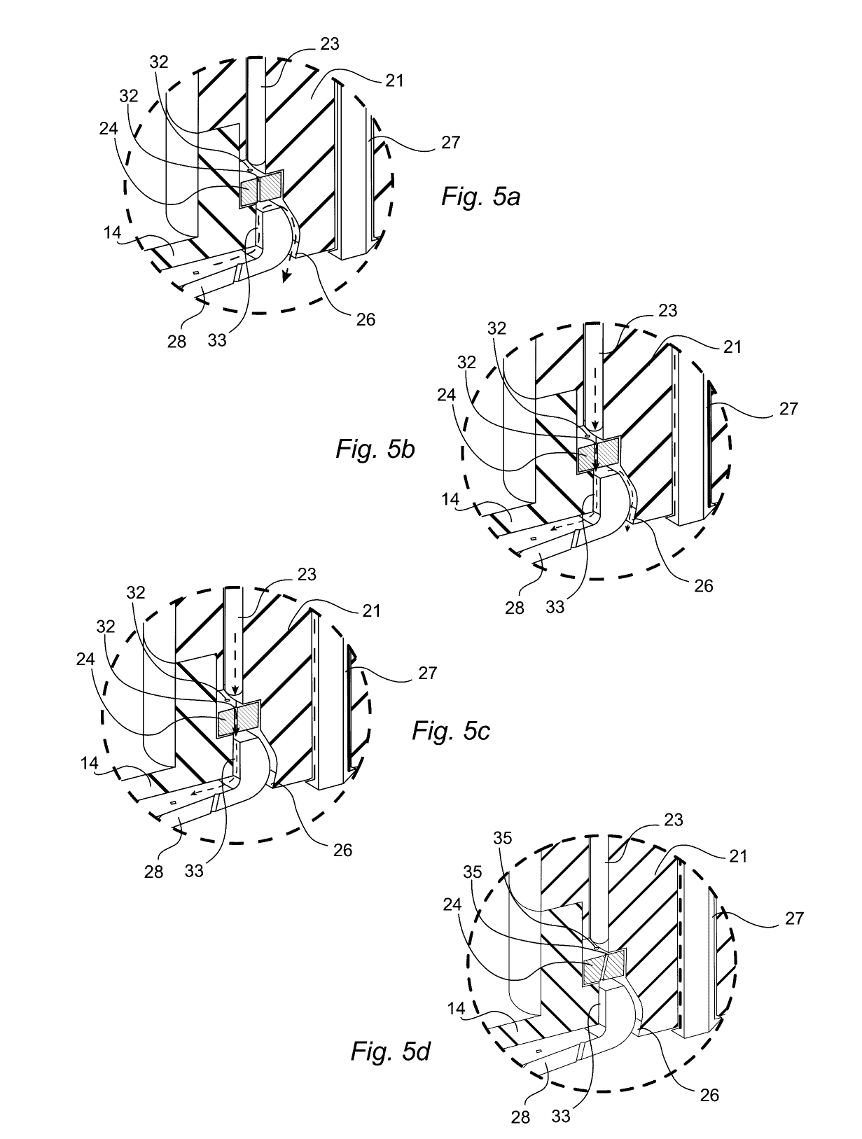

In particular, as shown in FIG. 5a, when the spin chuck is rotated and process gas is supplied to chamber 37, the rotation of showerhead plate 28 relative to the stationary lid 14 and nozzle assembly 21 induces an undesired flow of process fluid through the annular gap 33 that exists between the outer surface of plate 28 in the vicinity of the central opening, and the inner annular surface of lid 14. Process gas drawn through the annular gap 33 then passes through the annular gap 26, as shown by the dashed arrow line in FIG. 5a, where it disproportionately treats a central region of a wafer W held by the spin chuck. This is the condition in which no gas is supplied through the conduit 23.

For example, photoresist removal may be performed using a highly reactive gas including ozone, in a closed process chamber at high temperatures. A uniform rate of photoresist removal is required to meet the product specifications. However, with an uncontrolled gas leakage flow from the plate 28 to the annular gap 26, there is a high center peak in the photoresist removal and poor uniformity in the photoresist strip rate.

Turning now to FIG. 5b, the provision of at least one side nozzle 32 has been found to provide a solution to this undesired process gas flow problem. In particular, by supplying gas (which is preferably an inert gas such as N₂) through the conduit 23 to the annular nozzle block 24 and through the side nozzles 32, the undesired flow of process gas through gaps 33 and 26 can be reduced or stopped altogether. In particular, the broken line arrows in FIG. 5b represent inert gas from nozzle 32 flowing into the gap 33, and a reduced flow of process gas flowing into the gap 26.

FIG. 5c shows the case wherein the flow of inert gas through conduit 23 and gap 33 is sufficient to prevent any process gas from flowing into the gap 26.

It will be noted that the bore of nozzles 32 is significantly narrower than the area of the flow paths at the inlet and outlet of nozzles 32. Nozzles 32 are moreover positioned adjacent to yet radially outside of the gap 26. Thus, as inert gas passes through and is discharged from the nozzles 32, the inert gas is accelerated within the nozzles 32, which in turn generates a reduced pressure at the upper end of the annular gap 26, via the Venturi effect. This reduced pressure impedes or prevents the undesired flow of process gas into the gap 26, as would otherwise occur as shown in FIG. 5a.

Furthermore, this effect can be tuned by varying the velocity of flow through the nozzles 32, so as to permit a reduced flow of process gas through the annular gap 32, or to prevent process gas from entering the gap 26 altogether, or even to induce a reverse flow of gas upward through the annular gap 26.

FIG. 5d shows an alternative embodiment in which the side nozzles 35 do not extend vertically as was the case for side nozzles 32, but instead have their upper inlets positioned radially inwardly of their lower outlets. The side nozzles 35 thus extend obliquely, which has been found to be advantageous for certain applications. Alternatively, side nozzles 35 could extend obliquely in the opposite direction, that is, with their upper inlets positioned radially outwardly of their lower outlets.

While the present invention has been described in connection with various preferred embodiments thereof, it is to be understood that those embodiments are provided merely to illustrate the invention, and that the invention is not limited to those embodiments, but rather includes that which is encompassed by the true scope and spirit of the appended claims.

What is claimed is:

1. An apparatus for processing wafer-shaped articles, comprising:
a process chamber;
a spin chuck positioned inside said process chamber, said spin chuck being configured to hold a wafer-shaped article at a predetermined process position;
a plate covering said spin chuck and being affixed to or formed integrally with said spin chuck for rotation therewith, said plate having a central opening; and
a nozzle assembly that extends into said process chamber such that a discharge end of said nozzle assembly passes through the central opening of said plate to define a gap between said central opening and said nozzle assembly, said gap extending from an upper inlet end to a lower outlet end;
said nozzle assembly comprising at least one side nozzle positioned to direct a gas flow adjacent to said gap and upstream of said lower outlet end, and configured to generate a reduced pressure at a position upstream of said lower outlet end of said gap, thereby to control gas flow through said gap from said upper inlet end toward said lower outlet end.

2. The apparatus according to claim 1, wherein said plate and an upper part of said process chamber define a gas distribution chamber, and wherein said plate comprises plural openings formed in each of a central and a peripheral region thereof, thereby to supply process gas from said gas distribution chamber to a surface of a wafer-shaped article when held by said spin chuck.

3. The apparatus according to claim 2, further comprising at least one gas supply nozzle positioned radially outside of said nozzle assembly, said at least one gas supply nozzle supplying process gas to said gas distribution chamber.

4. The apparatus according to claim 2, wherein said plate is domed such that a central region thereof is positioned farther from a wafer-shaped article when positioned on said spin chuck than a peripheral region thereof.

5. The apparatus according to claim 2, wherein each of said plural openings has a cross-sectional area in a range from 0.3 to 2.0 mm².

6. The apparatus according to claim 2, wherein said plural openings includes at least 20 of said openings.

7. The apparatus according to claim 1, wherein said at least one side nozzle comprises at least three side nozzles, positioned symmetrically with respect to said gap.

8. The apparatus according to claim 1, wherein said at least one side nozzle comprises a constricted section having an outlet communicating with a wider section adjacent to and communicating with said upper inlet end of said gap, thereby to generate said reduced pressure via the Venturi effect.

9. The apparatus according to claim 8, wherein said constricted section is oriented such that a flow path thereof is generally parallel to an axis of rotation of said spin chuck.

10. The apparatus according to claim 8, wherein said constricted section is oriented such that a flow path thereof extends obliquely to an axis of rotation of said spin chuck, with an inlet of said constricted section being closer to an axis of rotation of said spin chuck than said outlet.

11. The apparatus according to claim 1, wherein said plate is domed such that a central region thereof is positioned farther from a wafer-shaped article when positioned on said spin chuck than a peripheral region thereof.

12. The apparatus according to claim 1, wherein said nozzle assembly comprises a liquid supply conduit and a gas supply conduit, each of said liquid supply conduit and said gas supply conduit opening at said discharge end of said nozzle assembly, at a level below said lower outlet end of said gap.

13. The apparatus according to claim 1, wherein said central opening of said plate is a circular opening having a diameter of 30-60 mm

14. The apparatus according to claim 1, wherein said spin chuck comprises a magnetic rotor, said apparatus further comprising a magnetic stator mounted outside of said process chamber and surrounding said magnetic rotor.
